(19) United States
(12) Patent Application Publication
(10) Pub. No.: US 2026/0290762 A1
(43) Pub. Date: Sep. 24, 2026

(54) SEMICONDUCTOR PROCESSING EQUIPMENT AND CONTROL METHOD THEREOF

(71) Applicant: Taiwan Semiconductor Manufacturing Company, Ltd., Hsinchu (TW)

(72) Inventors: Fung-Chih HUANG, Hsinchu (TW); Wen-Wei FAN, Hsinchu (TW)

(73) Assignee: Taiwan Semiconductor Manufacturing Company, Ltd., Hsinchu (TW)

(21) Appl. No.: 19/085,791

(22) Filed: Mar. 20, 2025

(51) Int. Cl. H01J 37/32; H01L 21/67; H02K 7/116

(52) U.S. Cl. CPC H01J 37/32669; H02K 7/116; H01J 2237/334; H10P 72/0421

(57) ABSTRACT

A semiconductor processing equipment includes a vacuum chamber, a driving device and a vibration sensor. The vacuum chamber is configured to accommodate a semiconductor substrate, and the driving device is rotatably disposed around the vacuum chamber. The driving device includes a motor, a driving wheel and a first ring gear. The driving wheel is disposed on the rotating shaft of the motor, and the driving wheel is configured to engage the first ring gear to drive the ring gear to rotate. The vibration sensor is disposed on the driving device. The vibration sensor is configured to detect the vibration transmitted to the vibration sensor due to the rotation of at least one of the motor, the driving wheel and the first ring gear.

### BACKGROUND

As an etching method for etching the surface of a semiconductor substrate according to a predetermined pattern, a wet etching method using a liquid (alkali or acid solvent) has conventionally been known. Recently, a dry etching method by using gas plasma has been widely adopted, in which a liquid cleaning step and a subsequent drying step can be omitted, and fine patterns can be accurately completed.

The plasma rotation in the etching machine is made by the rotation of magnets. Vibration of magnets may occur due to unstable rotation of gears or motors, or severe vibration may occur due to dry friction of gear rotation. For example, dry lubricating oil may cause positional shift, resulting in wafer process alarms or poor yield.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic side view of a semiconductor processing equipment according to an embodiment of the present disclosure.

FIG. 2 is a schematic top view of a semiconductor processing equipment according to an embodiment of the present disclosure.

FIG. 3 is a schematic diagram of a vibration control method for a semiconductor processing equipment according to an embodiment of the present disclosure.

FIG. 4 is a flow chart of a vibration control method for a semiconductor processing equipment according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

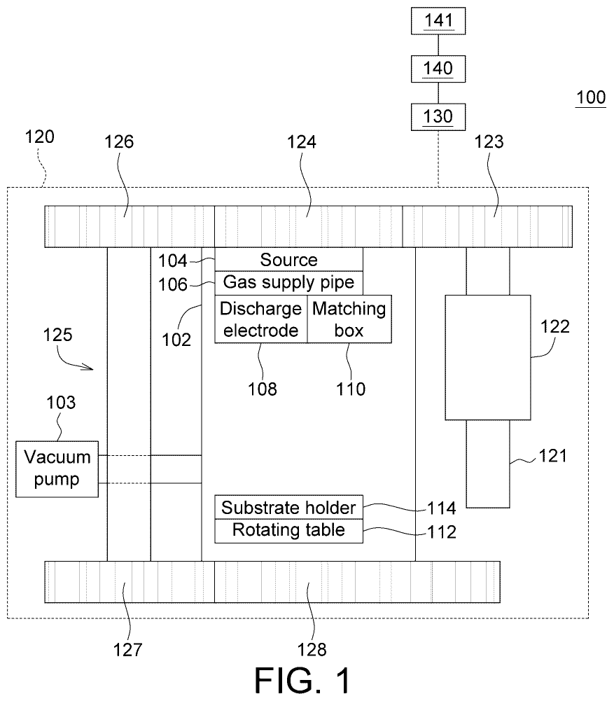

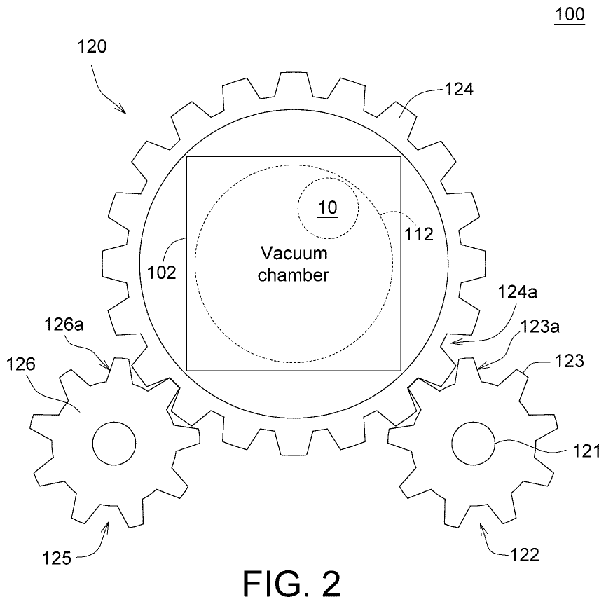

Please refer to FIGS. 1 and 2. FIG. 1 illustrates a schematic side view of a semiconductor processing equipment 100 according to an embodiment of the present disclosure. FIG. 2 illustrates a schematic top view of a semiconductor processing equipment 100 according to an embodiment of the present disclosure. The semiconductor processing equipment 100 is, for example, a dry etching equipment or other equipment with ion beam bombardment, used to etch the surface of the semiconductor substrate 10. As dry etching methods, generally known are chemical dry etching (called CDE) for operating a chemical etching mechanism, reactive ion etching (called RIE) for operating a chemical and physical etching mechanism, and sputter etching for operating a physical etching mechanism.

Under some circumstances, the processing capabilities of the dry etching equipment are limited, leaving problems in improving productivity and yield. Especially in recent years, the demand for larger semiconductor substrates 10 has been increasing. However, in existing dry etching equipment, as the object to be etched becomes larger, the etching processing capacity may decrease. In particular, vibration or imbalance of the etching machine may cause semiconductor substrate 10 to shift or cause contaminants to fall on the semiconductor substrate 10, or cause abnormal plasma rotation in the chamber to cause local defects in the semiconductor substrate 10. If the vibration of the machine is severe, the alarm system will issue a warning and shut down, which will also cause a reduction in productivity and yield.

Referring to FIGS. 1 and 2, the semiconductor processing equipment 100 includes a vacuum chamber 102, a driving device 120 and a vibration sensor 130. The vacuum chamber 102 can be connected to an external vacuum pump 103 (or vacuum source), and the vacuum pump 103 makes the inside of the vacuum chamber 102 under a predetermined vacuum state. The driving device 120 is rotatably disposed around the vacuum chamber 102, and the vibration sensor 130 is disposed on the driving device 120 for detecting the vibration generated by the driving device 120.

In one embodiment, inside the vacuum chamber 102, a gas supply source 104 and a plurality of gas supply tubes 106 for guiding gas from the gas supply source 104 to the interior of the vacuum chamber 102 are disposed. In addition, the discharge electrodes 108 are respectively disposed inside the vacuum chamber 102 for changing the gas flowing into the vacuum chamber 102 into plasma, active ions, or both plasma and active ions to serve as a plasma source. The gas supply unit may be structurally provided with a microwave introduction device (not shown) for introducing microwaves to pre-change the gas supplied into the vacuum chamber 102 into plasma, active ions, or both plasma and active ions. When the power supplied to the discharge electrodes 108 is high-frequency power, the dry etching apparatus preferably has a built-in phase shifter for controlling the phase of the high-frequency power supplied to the discharge electrode 108 and a built-in bias controller for controlling a direct current self-bias of the discharge electrodes 108, thereby the power from the high-frequency power supply can be fed to each of the discharge electrodes 108 via the above-mentioned control circuit.

The above structure can be applied to so-called Carnot unit type dry etching equipment, in which a rotating table 112 and several substrate holders 114 can be structurally configured in the vacuum chamber 102, and the substrate holders 114 concentrically arranged in the circumference of the rotating table 112 are used to support a plurality of semiconductor substrates 10 etched on the respective upper and lower surfaces thereof inside the vacuum chamber 102.

In addition, the discharge electrodes 108 and the gas supply tube 106 are concentrically opposed to each other on the upper surface and the lower surface of the substrate holder 114 along the moving positions of the semiconductor substrates 10. The above structure can be applied to so-called in-line dry etching equipment, in which a linearly movable conveyor belt is disposed in the vacuum chamber 102, and a plurality of substrate holders 114 are disposed on the conveyor belt to support the semiconductor substrates 10 etched on the respective upper and lower surfaces thereof, and the discharge electrodes 108 and the gas supply tube 106 can be linearly opposed to each other along the moving positions of the semiconductor substrates 10 on the upper and lower surfaces of each substrate holder 114.

In the case of supplying plasma, active ions, or both plasma and active ions in advance by introducing microwaves from the microwave introduction device, inside the vacuum chamber 102, the gas becomes plasma and the active ions and discharge after the gas is supplied, and a large amount of plasma, a large amount of radical ions, or both are generated around the discharge electrodes 108. As a result, the etching rate increases.

When high-frequency power is simultaneously supplied to the plurality of discharge electrodes 108 arranged inside the vacuum chamber 102, the generation of plasma is unstable, and therefore many problems such as charging or abnormality may often occur. Then, an anode electrode (not shown) is provided near each of the discharge electrodes 108 so that these problems can be prevented. As another means, the dry etching equipment is equipped with a matching box 110 that has a built-in phase shifter and a built-in bias controller. Power from the high-frequency power is supplied to the discharge electrodes 108 through the matching device 110, thereby performing phase control of the high-frequency power and DC self-bias control of the discharge electrode 108 to make the dry etching equipment in the most appropriate state. Therefore, mutual interference does not occur between these discharge electrodes 108, and plasma and the like are stably generated. In addition, by applying high-frequency voltage pulses in series or in a pulse state, abnormal discharge can be prevented and the etching shape can be controlled.

In one embodiment, the driving device 120 includes a motor 122, a driving wheel 123, a first ring gear 124, a second ring gear 128 and an idler gear 125. The motor 122 is configured to receive an electric power to drive the driving wheel 123, the first ring gear 124, the second ring gear 128 and the idler gear 125 to rotate respectively and/or rotate around the vacuum chamber 102. As shown in FIG. 1, the driving wheel 123 is disposed on the rotating shaft 121 of the motor 122. The driving wheel 123 is configured to engage the first ring gear 124 to drive the first ring gear 124 to rotate. The first ring gear 124 has teeth 124a arranged in an annular shape, and the driving wheel 123 also has teeth 123a arranged in an annular shape, and the teeth 123a and 124a mesh with each other. However, due to long-term friction, there is a gap between the teeth 123a and the teeth 124a due to completely fitting, thus causing vibration when the driving wheel 123 rotates. In addition, the rotor inside the motor 122 also deteriorates due to long-term use and causes vibration.

In addition, the first ring gear 124 and the second ring gear 128 are substantially concentrically arranged and parallel to each other so as to be separated by a predetermined distance. The idler gear 125 has a first gear 126 and a second gear 127 respectively at both ends. The first gear 126 meshes with the first ring gear 124, and the second gear 127 meshes with the second ring gear 128. Therefore, the idler gear 125 can be rotatably engaged with the first ring gear 124 and the second ring gear 128 through the first gear 126 and the second gear 127 respectively. As mentioned above, the teeth 126a of the idler gear 125 may incompletely mesh with the teeth 124a of the first ring gear 124 and the second ring gear 128 due to long-term friction, and thus there is a gap between the teeth 124a and the teeth 126a due to completely fitting. Therefore, this causes vibration when the idler gear 125, the first ring gear 124 and/or the second ring gear 128 rotates.

In some embodiments, a first permanent magnet 131 is disposed on the annular surface of the first ring gear 124, and a second permanent magnet 132 is disposed on the annular surface of the second ring gear 128. The first permanent magnet 131 and the second permanent magnet 132 are concentrically arranged and parallel to each other so as to be separated by a predetermined distance. The first ring gear 124 and the second ring gear 128 rotate synchronously at the constant speed (for example, 10 to 20 revolutions per minute), and the first permanent magnet 131 and the second permanent magnet 132 also rotate synchronously at the constant speed. When at least one of the motor 122, the driving wheel 123, the idler gear 125, the first ring gear 124 and the second ring gear 128 vibrates, the first permanent magnet 131 and the second permanent magnet 132 will rotate unsteadily.

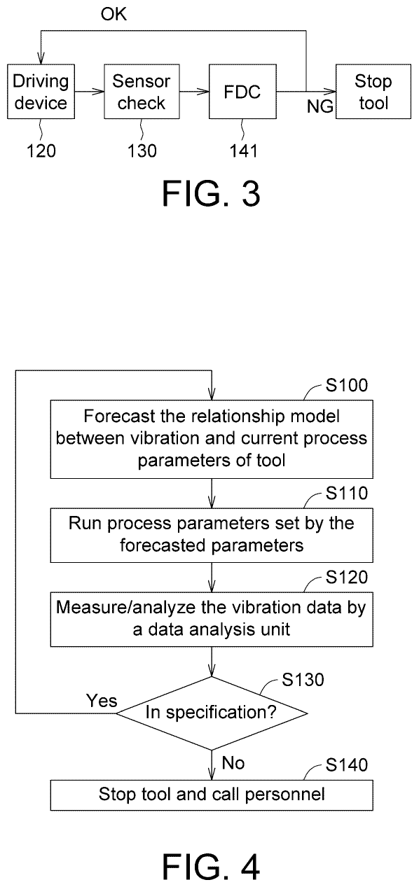

Please refer to the schematic diagram in FIG. 3. In order to avoid the rotational vibration of the first permanent magnet 131 and the second permanent magnet 132 causing abnormal plasma rotation in the vacuum chamber 102, and thereby causing local defects on the semiconductor substrate 10 due to abnormal etching, in this embodiment, the vibration generated by the driving device 120 is detected through the vibration sensor 130, and the obtained data is sent to a data analysis unit 141 (such as FDC, which can be a hardware, software or an algorithm) to determine whether the vibration amplitude of the driving device 120 is greater than a threshold. When the vibration amplitude is greater than the threshold (i.e., it is not good), the semiconductor processing equipment 100 can be notified to shut down for personnel to inspect or replace components; when the vibration amplitude is less than or equal to the threshold (i.e., it is OK), it means that the vibration amplitude is within an allowable range, so the semiconductor processing equipment 100 can continue to operate.

Please refer to FIG. 4. FIG. 4 illustrates a flow chart of a vibration control method for a semiconductor processing equipment 100 according to an embodiment of the present disclosure. First, in step S100, the relationship model between the operating parameters of the semiconductor processing equipment 100 and the vibration amplitude of the driving device 120 can be forecasted through big data analysis or parameter matching, or the relationship model between the operating parameters of the semiconductor processing equipment 100 and the vibration amplitude of the driving device 120 can be forecasted through neural networks and machine learning (or deep learning). Then, in step S110, actual operation is performed with the forecasted parameters of the semiconductor processing equipment 100 to obtain actual vibration amplitude of the driving device 120, then, in step S120, the obtained vibration data is sent to a data analysis unit 141 to determine whether the vibration amplitude of the driving device 120 is greater than a threshold. In step S130, when the vibration amplitude is greater than the threshold, in step 140, the semiconductor processing equipment 100 can be notified to shut down for personnel to inspect or replace components; in step S130, when the vibration amplitude is less than or equal to the threshold, it means that the vibration amplitude is within the allowable range of specification, then returning to step S100 and the semiconductor processing equipment 100 can continue to operate.

In step S110, when the semiconductor processing equipment 100 is actually operated with the forecasted parameters, the semiconductor processing equipment 100 can collect transient vibration data transmitted every second by the control unit (i.e., machine control unit, MCU) 140. When the transient vibration data shows that the vibration amplitude exceeds a preset value (for example, 0.5 ms), the control unit 140 automatically performs offset correction of the semiconductor substrate 10. For example, the control unit 140 can control the robot arms of the substrate holders 114 to automatically perform a position offset, such as automatically shifting the semiconductor substrate 10 using the robot arm by 0.1 mm or more so that the positions of the substrate holders 114 and the discharge electrodes 108 are generally linearly opposite to each other.

The data analysis unit 141, also known as the failure detection and classification unit (FDC), is configured to collect the temporal data of the machines, and provides single-variable and multi-variable analysis according to the process status and requirements for monitoring and anomaly detection. The FDC can be used to establish a relationship model between the operating parameters of the semiconductor processing equipment 100 and the vibration amplitude of the driving device 120. If an abnormal operation occurs, the system immediately issues alarms and takes appropriate contingency measures (such as shutting down or notifying engineers) to the products (such as the semiconductor substrates 10) and the tools (such as the semiconductor processing equipment 100). Especially in advanced semiconductor manufacturing processes. As semiconductor processing technology continues to shrink, process offset or defects are usually not caused by a single process tool parameter, but are more likely to be the comprehensive impact of multiple parameters. Therefore, it is difficult to use traditional single variable analysis to find the root cause of the problem. Furthermore, real-time specification control of a single variable usually cannot detect abnormal behavior of the process tools. Therefore, this disclosure can further analyze which component of the driving device 120 the vibration source comes from through the collected vibration data. For example, the FDC can analyze the vibration types and vibration waveforms from respective idler gear 125 and motor 122 to forecast the relationship model between the operating parameters of the semiconductor processing equipment 100 and the vibration amplitude of the driving device 120.

The present disclosure relates to a semiconductor processing equipment and a control method thereof. In some embodiments, the vibration generated by the driving device is detected through the vibration sensor, and the obtained vibration data is sent to a data analysis unit (such as FDC) to determine whether the vibration amplitude of the driving device is greater than a threshold in order to avoid the rotational vibration of the driving device causing abnormal plasma rotation in the vacuum chamber, and thereby preventing local defects on the semiconductor substrate due to abnormal etching and improving the productivity and yield of the products.

According to some embodiments of the present disclosure, a semiconductor processing equipment includes a vacuum chamber, a driving device and a vibration sensor. The vacuum chamber is configured to accommodate a semiconductor substrate, and the driving device is rotatably disposed around the vacuum chamber. The driving device includes a motor, a driving wheel and a first ring gear. The driving wheel is disposed on the rotating shaft of the motor, and the driving wheel is configured to engage the first ring gear to drive the ring gear to rotate. The vibration sensor is disposed on the driving device. The vibration sensor is configured to detect the vibration transmitted to the vibration sensor due to the rotation of at least one of the motor, the driving wheel and the first ring gear.

According to some embodiments of the present disclosure, a method for controlling a semiconductor processing equipment is provided. The semiconductor processing equipment includes a vacuum chamber and a driving device. The vacuum chamber is configured to accommodate a semiconductor substrate, and the driving device is rotatably disposed around the vacuum chamber. The method for controlling the semiconductor processing equipment includes the following steps. A vibration sensor is provided on the driving device, which includes a motor, a driving wheel and a first ring gear. The driving wheel is driven to rotate around the rotation axis of the motor, and the driving wheel is configured to engage the first ring gear to drive the ring gear to rotate. The vibration sensor is configured to detect the vibration transmitted to the vibration sensor due to the rotation of at least one of the motor, the driving wheel and the first ring gear.

According to some embodiments of the present disclosure, a method for controlling a semiconductor processing equipment is provided, which includes the following steps. A relationship model between operating parameters of the semiconductor processing equipment and a vibration amplitude of a driving device is forecasted. An actual operation is performed with the forecasted parameters of the semiconductor processing equipment to obtain a vibration data of the driving device. The obtained vibration data is sent to a data analysis unit to determine whether the vibration amplitude of the driving device is greater than a threshold. A semiconductor processing is performed when the vibration amplitude is less than a predetermined threshold.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing equipment, comprising:
a vacuum chamber for accommodating a semiconductor substrate;
a driving device rotatably disposed around the vacuum chamber, wherein the driving device comprises a motor, a driving wheel and a first ring gear, the driving wheel is disposed on a rotating shaft of the motor, and the driving wheel is configured to engage the first ring gear to drive the first ring gear to rotate; and
a vibration sensor disposed on the driving device, the vibration sensor is configured to detect a vibration transmitted to the vibration sensor due to a rotation of at least one of the motor, the driving wheel and the first ring gear.

2. The semiconductor processing equipment of claim 1, wherein the driving device further comprises a first permanent magnet, the first permanent magnet is disposed on an annular surface of the first ring gear.

3. The semiconductor processing equipment of claim 2, wherein the driving device further comprises an idler gear and a second ring gear, the idler gear has a first gear and a second gear at both ends of the idler gear, and the first gear meshes with the first ring gear and the second gear meshes with the second ring gear.

4. The semiconductor processing equipment of claim 3, wherein the first ring gear and the second ring gear are concentrically arranged and parallel to each other so as to be separated by a predetermined distance.

5. The semiconductor processing equipment of claim 3, wherein the driving device further comprises a second permanent magnet, the second permanent magnet is disposed on an annular surface of the second ring gear.

6. The semiconductor processing equipment of claim 3, wherein the motor drives the first ring gear and the second ring gear to rotate synchronously at a constant speed.

7. The semiconductor processing equipment of claim 1, further comprising a data analysis unit coupled to the vibration sensor, and the data analysis unit is configured to determine whether a vibration amplitude of the driving device is greater than a threshold.

8. The semiconductor processing equipment of claim 7, wherein the data analysis unit comprises a failure detection and classification unit for establishing a relationship model between operating parameters of the semiconductor processing equipment and the vibration amplitude of the driving device.

9. The semiconductor processing equipment of claim 7, further comprising a control unit coupled to the vibration sensor and the data analysis unit, the control unit being used to collect transient vibration data transmitted from the driving device, when the transient vibration data shows that the vibration amplitude exceeds a preset value, the control unit automatically performs offset correction of the semiconductor substrate.

10. A method for controlling a semiconductor processing equipment, comprising:
disposing a vibration sensor on a driving device, the driving device comprises a motor, a driving wheel and a first ring gear; and
driving the driving wheel to rotate around a rotation axis of the motor, wherein the driving wheel is configured to engage the first ring gear to drive the first ring gear to rotate, the vibration sensor is configured to detect a vibration transmitted to the vibration sensor due to a rotation of at least one of the motor, the driving wheel and the first ring gear.

11. The method of claim 10, wherein the semiconductor processing equipment comprises a vacuum chamber, the vacuum chamber is configured to accommodate a semiconductor substrate, and the driving device is rotatably disposed around the vacuum chamber.

12. The method of claim 10, wherein the driving device further comprises a first permanent magnet, the first permanent magnet is disposed on an annular surface of the first ring gear.

13. The method of claim 12, wherein the driving device further comprises an idler gear and a second ring gear, the idler gear have a first gear and a second gear on both ends of the idler gear respectively, the first ring gear meshes with the first ring gear, and the second gear meshes with the second ring gear.

14. The control of claim 13, wherein the first ring gear and the second ring gear are concentrically arranged and parallel to each other so as to be separated by a predetermined distance.

15. The method of claim 13, wherein the driving device further comprises a second permanent magnet, the second permanent magnet is disposed on an annular surface of the second ring gear.

16. The method of claim 13, further comprising driving the first ring gear and the second ring gear to rotate synchronously at a constant speed by the motor.

17. The method of claim 10, further comprising determining whether a vibration amplitude of the driving device is greater than a threshold by a data analysis unit.

18. The method of claim 17, further comprising establishing a relationship model between operating parameters of the semiconductor processing equipment and the vibration amplitude of the driving device by a failure detection and classification unit.

19. The method of claim 17, further comprising collecting transient vibration data transmitted from the driving device by a control unit, when the transient vibration data shows that the vibration amplitude exceeds a preset value, the control unit automatically performs offset correction of the semiconductor substrate.

20. A method for controlling a semiconductor processing equipment, comprising:
forecasting a relationship model between operating parameters of the semiconductor processing equipment and a vibration amplitude of a driving device;
performing an actual operation with the forecasted parameters of the semiconductor processing equipment to obtain a vibration data of the driving device;
sending the obtained vibration data to a data analysis unit; and
performing a semiconductor processing when the vibration amplitude is less than a predetermined threshold.
